(19) United States
(12) Patent Application Publication
(10) Pub. No.: US 2026/0090366 A1
(43) Pub. Date: Mar. 26, 2026

(54) SEMICONDUCTOR DEVICE AND METHOD OF FORMING THE SAME

(71) Applicant: Winbond Electronics Corp., Taichung City (TW)

(72) Inventor: Shou-Te WANG, Taichung City (TW)

(21) Appl. No.: 19/201,036

(22) Filed: May 7, 2025

(30) Foreign Application Priority Data
Sep. 18, 2024 (TW) 113135275

(51) Int. Cl. H10W 20/47; H10D 64/01; H10D 64/23; H10D 64/27

(52) U.S. Cl. CPC H10W 20/47; H10D 64/01; H10D 64/258; H10D 64/511

(57) ABSTRACT

A semiconductor device includes: a substrate; a gate structure disposed on the substrate; a first insulating layer covering the gate structure; a contact disposed through the first insulating layer, wherein the contact is laterally adjacent to the gate structure; a metal layer disposed on the first insulating layer and in physical contact with the contact; and a first dielectric layer covering a sidewall of the metal layer.

### CROSS REFERENCE TO RELATED APPLICATIONS

This application claims priority of Taiwan Patent Application No. 113135275, filed Sep. 18, 2024, the entirety of which is incorporated by reference herein.

### BACKGROUND

### Technical Field

The present disclosure relates to a semiconductor device and method of forming the same, and in particular, it relates to the configuration of a dielectric layer.

### Description of the Related Art

In the course of developing semiconductor devices (such as a dynamic random access memory (DRAM)), functional density (i.e., the number of interconnected devices per chip area) has generally increased while geometric size (i.e., the smallest component (or line)) has decreased. This scaling-down process generally provides benefits by increasing production efficiency and lowering the associated costs. Such scaling-down has also increased the complexity of design and uses more precise and reliable methods to incorporate integrated circuits (IC) into the device. Because this scaling-down continues, the process has also become more difficult to carry out. Therefore, forming reliable semiconductor devices at smaller dimensions has become a challenge.

### SUMMARY

An embodiment of the present disclosure provides a semiconductor device, which includes: a substrate; a gate structure disposed on the substrate; a first insulating layer covering the gate structure; a contact disposed through the first insulating layer, wherein the contact is laterally adjacent to the gate structure; a metal layer disposed on the first insulating layer and in physical contact with the contact; and a first dielectric layer covering a sidewall of the metal layer.

Another embodiment of the present disclosure provides a method of forming a semiconductor device, which includes: providing a substrate; forming a gate structure on the substrate; forming a first insulating layer covering the gate structure; forming a second insulating layer on the first insulating layer; forming a metal layer on the second insulating layer; and forming a first dielectric layer covering a sidewall of the metal layer.

### BRIEF DESCRIPTION OF THE DRAWINGS

FIGS. 1-7 illustrate cross-sectional views of various intermediate stages of forming a semiconductor device, according to some embodiments of the present disclosure.

FIG. 8 illustrates a top view of the semiconductor device, according to some embodiments of the present disclosure.

### DETAILED DESCRIPTION

In a semiconductor device, a complex circuit layout may be designed on the wafer. Specifically, when various metal layers are stacked, it is necessary to incorporate the planar insulating material between the metal layers. In the peripheral region of the DRAM, a metal layer may be formed on an insulating layer to serve as the source terminal and the drain terminal of a transistor, followed by covering the metal layer with another insulating layer. However, when the insulating layer and the metal layer are respectively oxide and tungsten, the metal layer may be readily oxidized during the subsequent process. Oxidation usually occurs during the subsequent process involving high temperature or high stress. The oxidized metal may be diffused outward. When the metal layer of the source terminal and the metal layer of the drain terminal are bridged together, the short circuitry of the transistor may be generated, causing the semiconductor device to fail.

The DRAM illustrated in the semiconductor device of the present disclosure may utilize a dielectric layer to cover the sidewall of the metal layer before the metal layer is covered by the insulating layer. Materials of the dielectric layer are different from those of the insulating layer, thus the metal oxidation leading to short circuitry may be effectively prevented. In other words, the sidewall of the metal layer may be separated from the subsequently formed insulating layer by the dielectric layer.

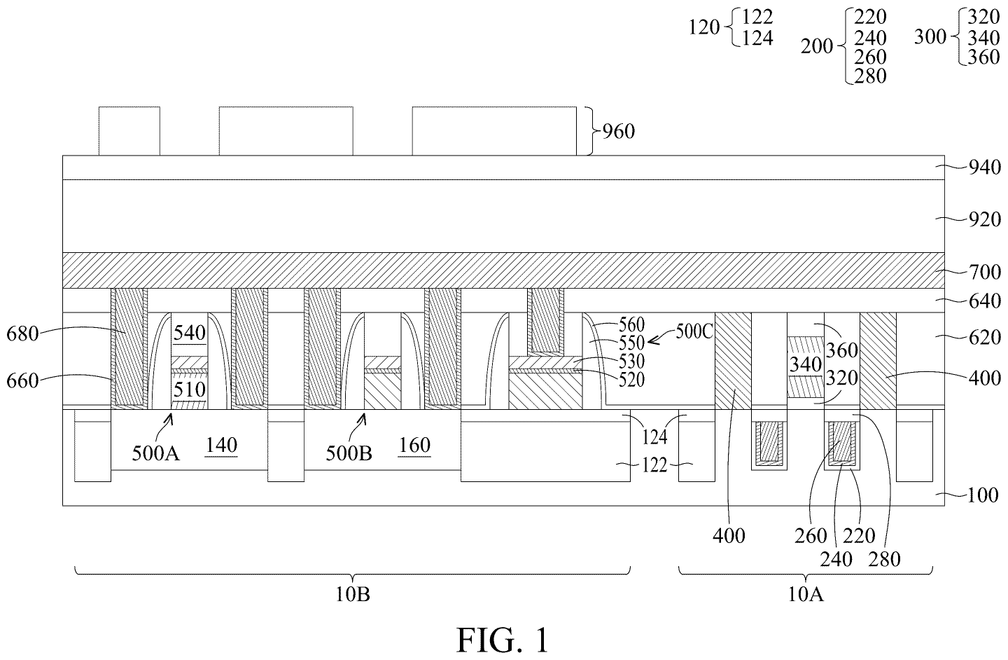

Referring to FIGS. 1-7, a semiconductor device 10 only illustrates cross-sectional views of various intermediate stages of a portion of the DRAM, in some embodiments.

Referring to FIG. 1, the semiconductor device 10 may be compartmentalized into a memory region 10A and a peripheral region 10B. The initial structure of the semiconductor device 10 may include a substrate 100, a shallow trench isolation (STI) structure 120, a well region 140, a well region 160, word lines 200, a bit line 300, capacitive contacts (CC) 400, a gate structure 500A, a gate structure 500B, a gate structure 500C, an insulating layer 620, an insulating layer 640, a liner 660, a contact 680, a metal material layer 700, a photoresist layer 920, an antireflective coating 940, a mask 960. The STI structure 120 may include an isolation layer 122 and a cap layer 124. The word lines 200 may each include a dielectric layer 220, a barrier layer 240, a conductive filling 260, and a cap layer 280. The bit line 300 may include a dielectric layer 320, a conductive layer 340, and a cap layer 360. The gate structure 500A, the gate structure 500B, and the gate structure 500C may each include a gate conductor (GC) 510, an adhesion layer 520, a conductive layer 530, a hard mask 540, a spacer 550, and a dielectric layer 560.

The substrate 100 may be a semiconductor substrate, for example, a silicon substrate, an elemental semiconductor, a compound semiconductor, an alloy semiconductor, or the like.

In one embedment, the substrate 100 may also be a semiconductor on insulator (SOI) substrate. The SOI substrate may include a base plate, a buried oxide (BOX) layer disposed on the base plate, and a semiconductor layer disposed on the buried oxide layer. For example, the buried oxide layer may be silicon dioxide (SiO₂).

Referring to FIG. 1, the STI structure 120 may be formed within the substrate 100 to define active regions and to electrically isolate active region elements within or above the substrate 100. In some embodiments, the isolation layer 122 may be soft oxides (such as spin-on oxides), while the cap layer 124 may be hard oxides (such as high-density plasma (HDP) oxides). In other embodiments, additional isolation structures may be adopted as alternatives, such as deep trench isolation (DTI) structures or local oxidation of silicon (LOCOS) structures. The formation of the STI structure 120 may include, for example, forming an insulating layer on the substrate 100. Trenches may be formed extending into the substrate 100 through the patterning process. The patterning process may include the lithography process and the etching process. In some embodiments, the lithography process may include photoresist coating, soft baking, exposure, post-exposure baking, development, the like, or a combination thereof. The etching process may include dry etch process, wet etch process, the like, or a combination thereof.

The dry etch process may include plasma etching, reactive ion etching (RIE), the like, or a combination thereof. Suitable etching gas (for example, methane (CH₄), nitrogen trifluoride (NF₃), ammonia (NH₃), or hydrogen fluoride (HF), the like, or a combination) may be used to perform the dry etch process.

The wet etch process may include soaking, spray, the like, or a combination thereof. In some embodiments, suitable etchants for the wet etch process may include ammonium hydroxide (NH₄OH), diluted hydrofluoric acid (dHF), tetra methyl ammonium hydroxide (TMAH, C₄H₁₃NO), ammonia (NH₃), ethylenediamine pyrocatechol (EDP), nitric acid (HNO₃), acetic acid (CH₃COOH), potassium hydroxide (KOH), the like, or a combination thereof.

Next, the trenches may first be filled with the soft oxides (such as the spin-on oxides). After that, the upper portion of the soft oxides may be removed by an etch back process to form a recess. Next, the recess may be filled with the hard oxides (such as the HDP oxides). An anneal process may then be performed on the insulating material (including the isolation layer 122 and the cap layer 124) in the trenches, followed by a planarization process (such as chemical mechanical polish (CMP) or the like) on the substrate 100 to remove excessive insulating materials, so the insulating material in the trenches may be levelled with the substrate 100.

Still referring to FIG. 1, the well region 140 and the well region 160 may be formed within the substrate 100 in the peripheral region 10B, and may be surrounded by the STI structure 120. According to some embodiments of the present disclosure, the well region 140 and the well region 160 may serve as the active region of the transistor including the gate structure 500A and the active region of the transistor including the gate structure 500B, respectively. The well region 140 and the well region 160 may be p-type and n-type, respectively. The p-type dopants may include boron (B), indium (In), aluminum (Al), or gallium (Ga), while the n-type dopants may include phosphor (P) or arsenic (As). The well region 140 and the well region 160 may be formed by ion implantation and/or diffusion process.

Referring to FIG. 1, a pair of the word lines 200 may be formed within the substrate 100 in the memory region 10A, and may be surrounded by the STI structure 120. First, trenches may be formed extending into the substrate 100, the method thereof may be similar to the formation of the STI structure 120.

In some embodiments, the dielectric layer 220 may be conformally formed along the trenches. Materials of the dielectric layer 220 may include high-k oxides. The dielectric layer 220 may be formed by any suitable deposition process.

In some embodiments, the barrier layer 240 may be conformally formed on the surface of the dielectric layer 220 in the trenches. Materials of the barrier layer 240 may be, for example, titanium nitride (TiN). The barrier layer 240 may be formed by any suitable deposition process.

In some embodiments, the conductive filling 260 may be filled into the remaining portion of the trenches on the surface of the barrier layer 240. Materials of the conductive filling 260 may include polysilicon, metal nitrides, metal silicide, metal carbides, metal oxides, or metals. According to some embodiments of the present disclosure, the conductive filling 260 may be formed of tungsten (W). The conductive filling 260 may be formed by physical vapor deposition (PVD), atomic layer deposition (ALD), plating, the like, or a combination thereof.

In some embodiments, the top portions of the dielectric layer 220, the barrier layer 240, and the conductive filling 260 may be recessed to form a smaller recess, followed by forming the cap layer 280 into the smaller recess. Materials of the cap layer 280 may include low-k dielectric nitrides, such as silicon nitride (SiN), silicon oxynitride (SiON), silicon carbonitride (SiCN), silicon oxynitrocarbide (SiOₓN_{y}C_{1-x-y}, where x and y are within the range from 0 to 1), or the like. The cap layer 280 may be formed by any suitable deposition process, followed by the planarization process (such as CMP) on the substrate 100 to remove excessive materials, so the top surface of the word lines 200 may be levelled with that of the substrate 100.

Still referring to FIG. 1, the dielectric layer 320, the conductive layer 340, and the cap layer 360 may be sequentially formed on the surface of the substrate 100 in the memory region 10A. In some embodiments, blanket layers of the dielectric layer 320, the conductive layer 340, and the cap layer 360 may first be formed covering the overall surface of the substrate 100. Materials of the dielectric layer 320 may be similar to those of the dielectric layer 220, materials of the conductive layer 340 may be similar to those of the conductive filling 260, and materials of the cap layer 360 may be similar to those of the cap layer 280. The blanket layers of the dielectric layer 320, the conductive layer 340, and the cap layer 360 may be formed by any suitable deposition process mentioned above.

In some embodiments, a patterned photoresist may be formed on the blanket layers. The patterned photoresist may be used as a mask to pattern the blanket layer of the cap layer 360. After that, the pattern of the cap layer 360 may be further transferred to the underlying blanket layers to form the conductive layer 340 and the dielectric layer 320, respectively. The cap layer 360, the conductive layer 340, and the dielectric layer 320 may be formed by etching process.

Referring to FIG. 1, the capacitive contacts 400 may be formed on the surface of the substrate 100 in the memory region 10A. Materials of the capacitive contacts 400 may be similar to those of the conductive filling 260. According to an embodiment of the present disclosure, the capacitive contacts 400 may be formed of tungsten. The capacitive contacts 400 may be formed by any suitable deposition process mentioned above.

Still referring to FIG. 1, the gate structure 500A, the gate structure 500B, and the gate structure 500C may be formed on the surface of the substrate 100 in the peripheral region 10B. In some embodiments, the gate structure 500A and the gate structure 500B may be disposed on the well region 140 and the well region 160, respectively. Since the well region 140 and the well region 160 may respectively be p-type and n-type, the gate structure 500A and the gate structure 500B may respectively be n-type and p-type. The gate structure 500C may be disposed on the STI structure 120, and may serve as another non-active circuit in the peripheral region 10B.

In some embodiments, the gate conductor 510 may be formed on the surface of the substrate 100. Materials of the gate conductor 510 may be similar to those of the conductive filling 260. According to an embodiment of the present disclosure, the gate conductor 510 may be formed of polysilicon. The gate conductor 510 may be formed by any suitable deposition process mentioned above.

In some embodiments, the adhesion layer 520 may be formed on the gate conductor 510. The adhesion layer 520 may strengthen the adhesion of the overall gate structures. According to an embodiment of the present disclosure, the adhesion layer 520 may be formed of titanium. During the subsequent anneal processes, titanium from the adhesion layer 520 may be reacted with silicon from the gate conductor 510 to form titanium disilicide (TiSi₂), which may reduce the overall gate resistance. The adhesion layer 520 may be formed by any suitable deposition process mentioned above.

In some embodiments, the conductive layer 530 may be formed on the adhesion layer 520. The conductive layer 530 may conduct signals for read and write. Materials of the conductive layer 530 may be similar to those of the conductive filling 260. According to an embodiment of the present disclosure, the conductive layer 530 may be formed of tungsten. The conductive layer 530 may be formed by any suitable deposition process mentioned above.

In some embodiments, the hard mask 540 may be formed on the conductive layer 530. According to some embodiments of the present disclosure, the hard mask 540 may function as an etch stop layer (ESL). Materials of the hard mask 540 may be similar to those of the cap layer 280. According to an embodiment of the present disclosure, the hard mask 540 may be formed of silicon nitride. The hard mask 540 may be formed by any suitable deposition process mentioned above.

In some embodiments, the spacer 550 may be formed on the sidewalls of the gate conductor 510, the adhesion layer 520, the conductive layer 530, and the hard mask 540. The spacer 550 may generate high capacitance effect between the gate structure and the neighboring contact. Materials of the spacer 550 may be similar to those of the STI structure 120. The spacer 550 may be formed by any suitable deposition process.

In some embodiments, the dielectric layer 560 may be formed on the spacer 550. In some embodiments, the dielectric layer 560 may be extended onto the surface of the substrate 100. According to some embodiments of the present disclosure, the dielectric layer 560 may improve capacitance effect and increase reading speed. Materials of the dielectric layer 560 may be similar to those of the cap layer 280. According to an embodiment of the present disclosure, the dielectric layer 560 may be formed of silicon nitride. The dielectric layer 560 may be formed by any suitable deposition process.

Referring to FIG. 1, the insulating layer 620 may be formed on the substrate 100. In some embodiments, the insulating layer 620 may cover the substrate 100, the STI structure 120, the word lines 200, the bit line 300, the capacitive contacts 400, the gate structure 500A, the gate structure 500B, and the gate structure 500C. Materials of the insulating layer 620 may include silicon oxide (SiO), silicon oxynitride, silicon oxynitrocarbide, tetra ethyl ortho silicate (TEOS), undoped silicate glass (USG), doped silicon oxide (such as boron-doped phospho-silicate glass (BPSG), fused silica glass (FSG), phospho-silicate glass (PSG), boron-doped silicate glass (BSG), or the like), low-k dielectric materials, or the like. The insulating layer 620 may be formed by any suitable deposition process.

Still referring to FIG. 1, the insulating layer 640 may be formed on the insulating layer 620 to function as an etch stop layer. Materials of the insulating layer 640 may be similar to those of the insulating layer 620. According to an embodiment of the present disclosure, the insulating layer 640 may be formed of TEOS. The insulating layer 640 may be formed by any suitable deposition process.

Referring to FIG. 1, the liner 660 and the contact 680 may be formed through the insulating layer 640 and the insulating layer 620 in the peripheral region 10B. In some embodiments, the liner 660 and the contact 680 may be located on opposite sides of the gate structure 500A and the gate structure 500B, and may function as a contact source (CS) or a contact drain (CD). Since the gate structure 500C is the other non-active circuit in the peripheral region 10B, the liner 660 and the contact 680 may be formed through the hard mask 540 of gate structure 500C.

In some embodiments, trenches may first be formed through the insulating layer 640 and the insulating layer 620. Next, the liner 660 may be conformally deposited along the trenches. According to some embodiments of the present disclosure, the liner 660 may strengthen the adhesion of the contact 680, and may separate the contact 680 from the insulating material. Materials of the liner 660 may be similar to those of the conductive filling 260. According to an embodiment of the present disclosure, the liner 660 may be formed of titanium nitride. The liner 660 may be formed by any suitable deposition process mentioned above.

In some embodiments, the contact 680 may be formed in the remaining space of the trenches. According to some embodiments of the present disclosure, the contact 680 may conduct the applied voltage to the underlying well regions or the other non-active circuit. Materials of the contact 680 may be similar to those of the conductive filling 260. According to an embodiment of the present disclosure, the contact 680 may be a composite structure of titanium and titanium nitride. The contact 680 may be formed by any suitable deposition process mentioned above. After that, a planarization process (such as CMP) may be performed on the top surface of the insulating layer 640 to remove excessive materials, allowing the top surfaces of the liner 660, the contact 680, and the insulating layer 640 are levelled.

Still referring to FIG. 1, the metal material layer 700 may be formed on the insulating layer 640. According to some embodiments of the present disclosure, the metal material layer 700 may be patterned into respective metal layers. Materials of the metal material layer 700 may be similar to those of the conductive filling 260. According to an embodiment of the present disclosure, the metal material layer 700 may be formed of tungsten. The metal material layer 700 may be formed by any suitable deposition process mentioned above.

Referring to FIG. 1, the photoresist layer 920 may be formed on the metal material layer 700. According to some embodiments of the present disclosure, the photoresist layer 920 may be used to pattern the underlying metal material layer 700. The photoresist layer 920 may be formed by spin-on coating.

Still referring to FIG. 1, the antireflective coating 940 may be formed on the photoresist layer 920. According to some embodiments of the present disclosure, the antireflective coating 940 may reduce optical reflection or diffraction during exposure. The antireflective coating 940 may be formed by any suitable deposition process mentioned above.

Referring to FIG. 1, the mask 960 may be formed on the antireflective coating 940. According to some embodiments of the present disclosure, the mask 960 may effectively control the critical dimension (CD) of the lithography process. The mask 960 may be formed by any suitable deposition process mentioned above.

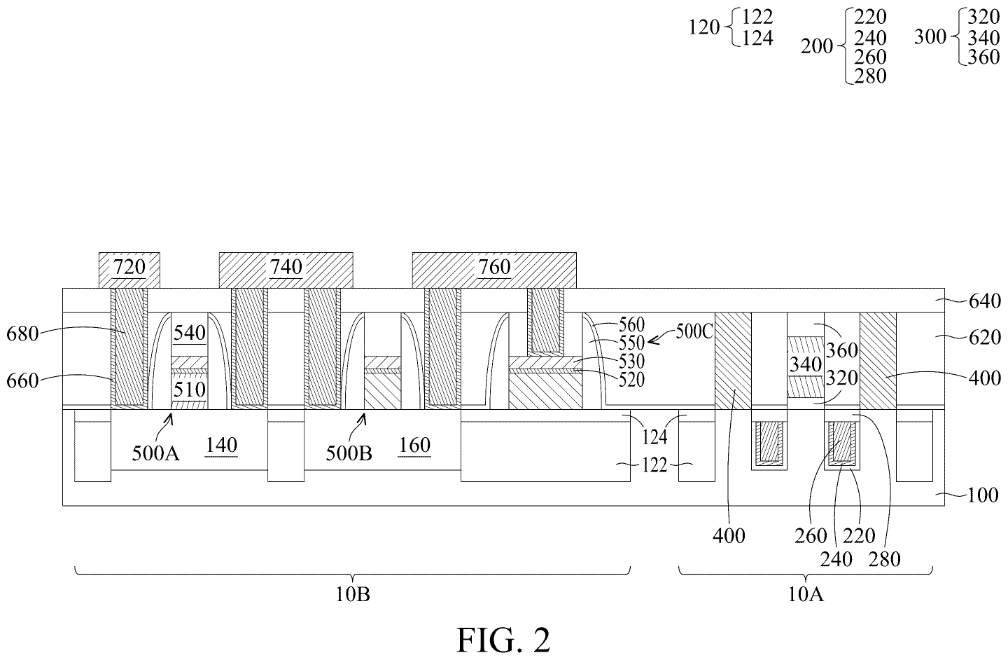

Referring to FIG. 2, the metal material layer 700 may be patterned into a metal layer 720, a metal layer 740, and a metal layer 760. In some embodiments, the metal layer 720, the metal layer 740, and the metal layer 760 may be in physical contact with the contact 680. The metal layer 720 may connect and correspond to the source terminal of the gate structure 500A, the metal layer 740 may connect and correspond to the drain terminal of the gate structure 500A and the source terminal of the gate structure 500B, and the metal layer 760 may connect and correspond to the drain terminal of the gate structure 500B and the gate structure 500C. According to some embodiments of the present disclosure, the metal layer 720, the metal layer 740, and the metal layer 760 may be applied voltages to the respective terminals. It should be appreciated that the pitch between the source terminal and the drain terminal of the gate structure 500A or the gate structure 500B is very narrow, for example, approximately 40 nm. Therefore, if the metal oxidation should occur, the short circuitry may be easily generated in the space between the source terminal and the drain terminal, causing the semiconductor device to fail. In some embodiments, the insulating layer 640 may be partially removed to form a recess in the process of patterning the metal material layer 700.

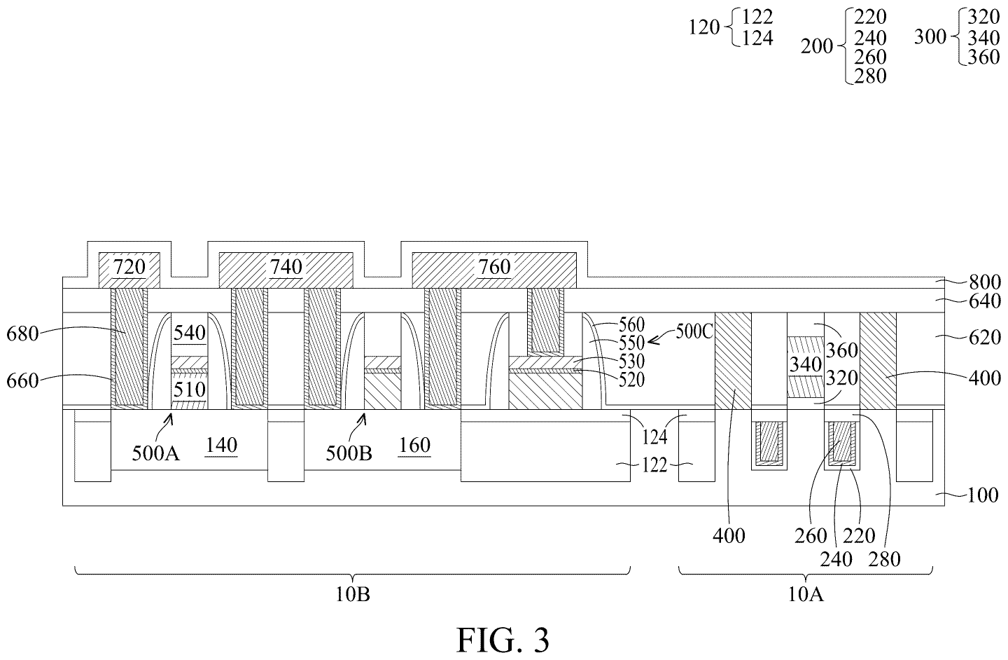

Referring to FIG. 3, a dielectric material layer 800 may be conformally deposited on the insulating layer 640, the metal layer 720, the metal layer 740, and the metal layer 760. According to a specific embodiment of the present disclosure, the dielectric material layer 800 may be formed by ALD. Due to the superior coverage of ALD, the dielectric material layer 800 may be effectively deposited between the source terminal and the drain terminal with the narrow pitch. The thickness of the dielectric material layer 800 may be between 5 nm and 10 nm. Materials of the dielectric material layer 800 may be similar to those of the dielectric layer 560, and the details are not described again herein to avoid repetition. In the embodiments where the insulating layer 640 is formed with the recess, the dielectric material layer 800 may also be conformally formed on the recess.

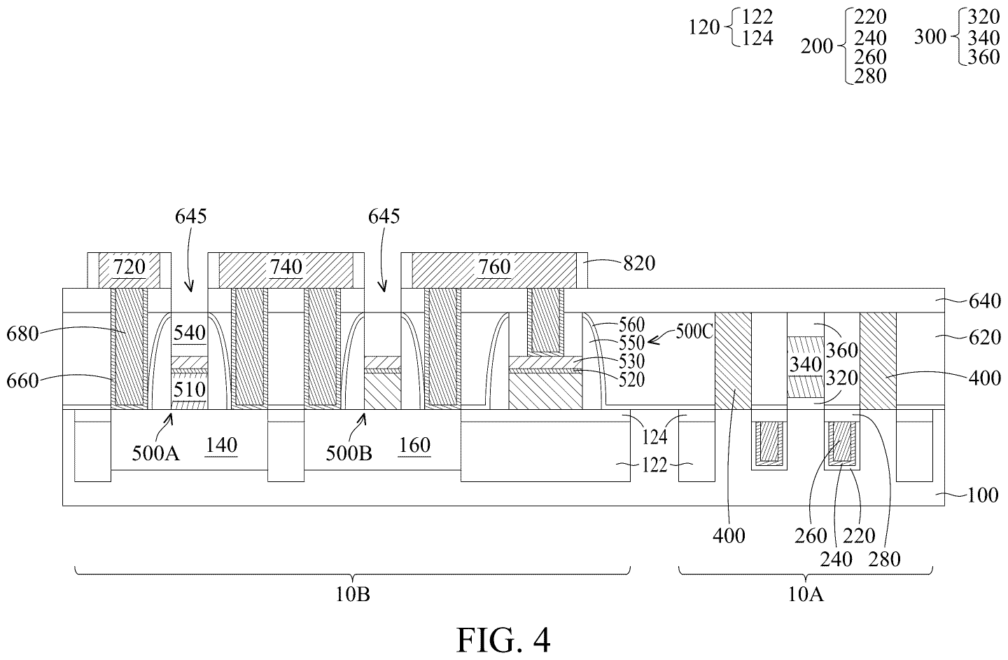

Referring to FIG. 4, the horizontal portions of the dielectric material layer 800 may be etched back. In some embodiments, the portions of the dielectric material layer 800 on the top surfaces of the metal layer 720, the metal layer 740, and the metal layer 760, as well as on the surface of the insulating layer 640 may be removed. The remaining portions of the dielectric material layer 800 covering the sidewalls of the metal layer 720, the metal layer 740, and the metal layer 760 become a dielectric layer 820. It should be appreciated that the etching process may have a relatively high etching rate in the narrow space. Therefore, the portions of the insulating layer 640 between the source terminal and the drain terminal of the gate structure 500A and the gate structure 500B may be further etched downward to form openings 645. The openings 645 may expose the top portions of the gate structure 500A and the gate structure 500B. It is worth noted that the pitches between the source terminal and the drain terminal of the gate structure 500A and the gate structure 500B, and the openings 645, collectively constitute a space with high aspect ratio. In the embodiments where the dielectric material layer 800 is conformally formed on the recess of the insulating layer 640, the bottom surface of dielectric layer 820 may be lower than the top surfaces of the metal layer 720, the metal layer 740, and the metal layer 760.

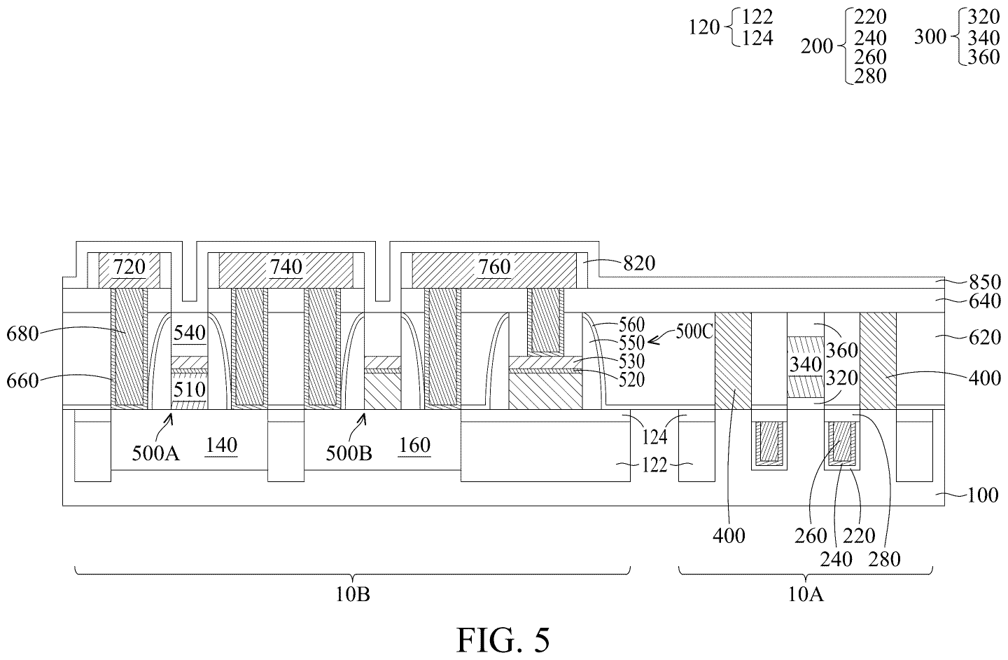

Referring to FIG. 5, a dielectric material layer 850 may be conformally deposited on the insulating layer 640, the metal layer 720, the metal layer 740, the metal layer 760, and the dielectric layer 820. In some embodiments, the dielectric material layer 850 may be further deposited in the openings 645. In some embodiments, the dielectric material layer 850 deposited in the openings 645 is V-shape. Due to the high aspect ratio, the dielectric material layer 850 may also fill the entire openings 645. According to some embodiments of the present disclosure, since the dielectric material layer 850 is extended downward beyond the bottom surfaces of the metal layer 720, the metal layer 740, and the metal layer 760, the potential risk of short circuitry may be more effectively prevented. Materials of the dielectric material layer 850 may be similar to those of the hard mask 540, and the details are not described again herein to avoid repetition. The material of the dielectric material layer 850 may be silicon nitride.

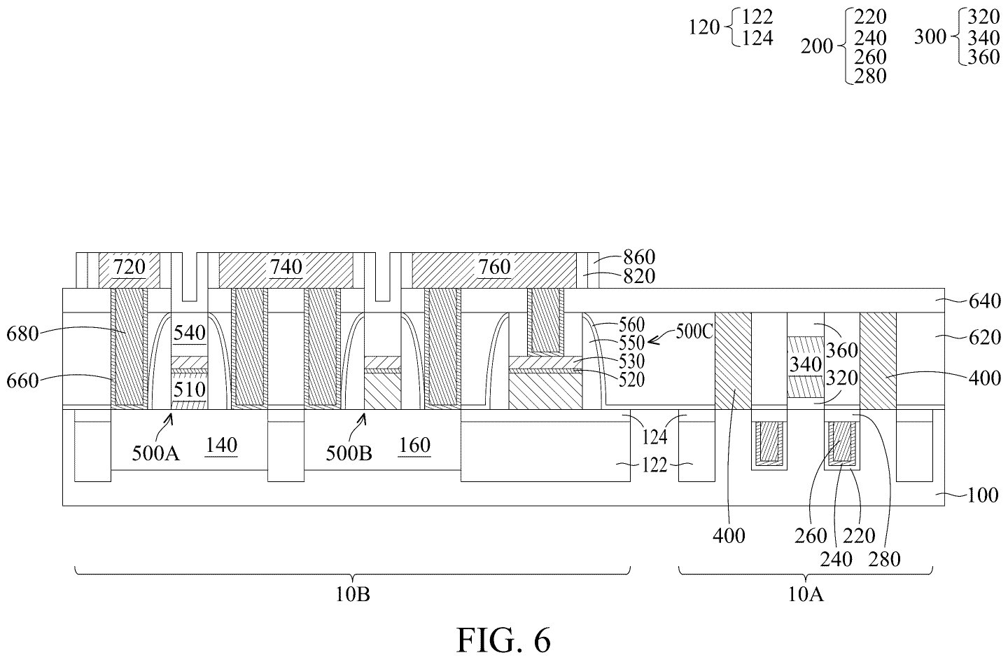

Referring to FIG. 6, an anisotropic etching may be performed on the surface of the entire structure to remove the horizontal portions of the dielectric material layer 850. In some embodiments, the portions of the dielectric material layer 850 on the top surfaces of the metal layer 720, the metal layer 740, and the metal layer 760, as well as on the surface of the insulating layer 640 may be removed. The remaining portions of the dielectric material layer 850 covering the sidewalls of the dielectric layer 820 become a dielectric layer 860. During the etching process, the process conditions may be set to immediately terminate when the signal from the metal (for example, tungsten) is detected. In other words, the etching would only be carried out until the top surfaces of the metal layer 720, the metal layer 740, and the metal layer 760 are exposed. Since the metal layer 720, the metal layer 740, and the metal layer 760 have a higher etching selectivity compared to the dielectric material layer 850, the etching process would not affect the integrity of the metal layer 720, the metal layer 740, and the metal layer 760. It should be appreciated that the portions of the dielectric material layer 850 within the space having the narrow pitch may not be etched due to the high aspect ratio of the space between the source terminal and the drain terminal of the gate structure 500A and the gate structure 500B.

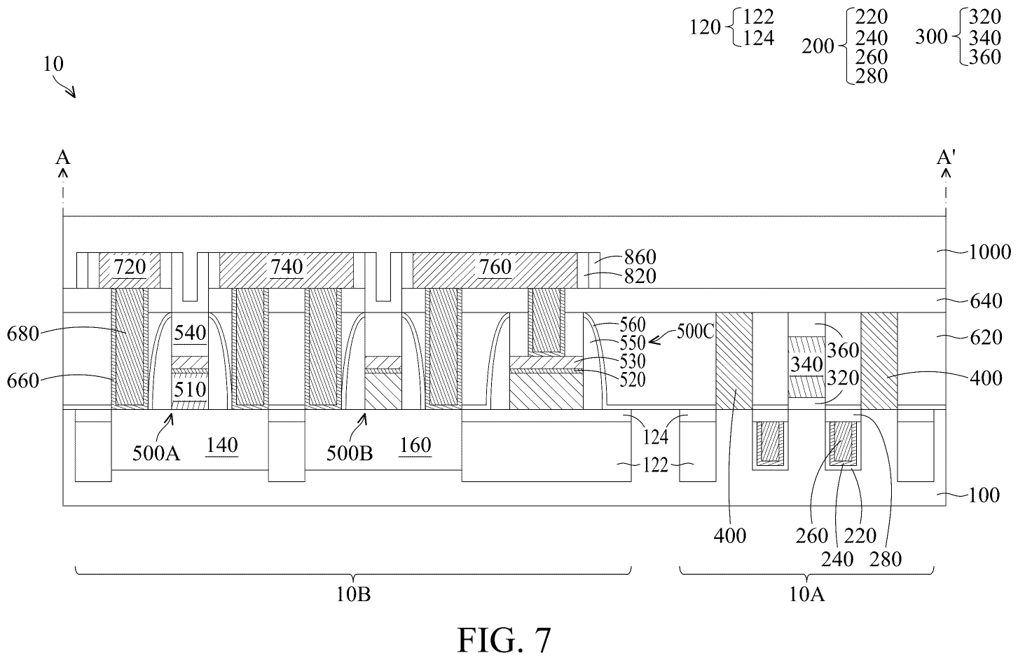

Referring to FIG. 7, an insulating layer 1000 may be formed on the insulating layer 640. In some embodiments, the insulating layer 1000 covers the metal layer 720, the metal layer 740, the metal layer 760, the dielectric layer 820, and the dielectric layer 860. In the conventional structure without the dielectric layer 820 and the dielectric layer 860, the insulating layer 1000 is in direct contact with the sidewalls of the metal layer 720, the metal layer 740, and the metal layer 760. During subsequent manufacturing processes involving high temperature and high stress, the metal material may be readily oxidized and diffused outward, leading to short circuitry. According to some embodiments of the present disclosure, the sidewalls of the metal layer 720, the metal layer 740, and the metal layer 760 may be separated from the insulating layer 1000 by the dielectric layer 820 and the dielectric layer 860. The insulating layer 1000 may be utilized for the back-end of line (BEOL) process of the DRAM.

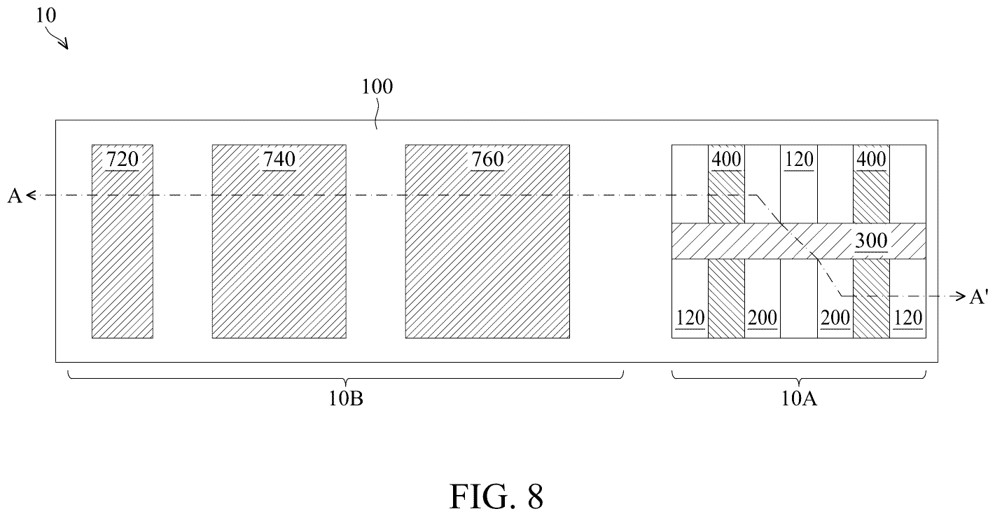

FIG. 8 illustrates a top view of the semiconductor device 10, according to some embodiments of the present disclosure. It is worth noted that FIG. 7 is the cross-sectional view obtained from a line A-A′ of FIG. 8. Since the extending direction of the word lines 200 is perpendicular to the extending direction of the bit line 300, cross-sectional view intends to show the word lines 200 and the bit line 300 simultaneously.

The semiconductor device of the present disclosure provides a combination of metal layers and dielectric layers. According to some embodiments of the present disclosure, the dielectric layers may first cover the sidewalls of the metal layers before the metal layers are covered by an insulating layer, thus the sidewalls of the metal layers may be separated from the subsequently formed insulating layer. Materials of the dielectric layers are different from those of the insulating layer, so the metal oxidation leading to short circuitry may be effectively prevented.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a gate structure disposed on the substrate;
a first insulating layer covering the gate structure;
a contact disposed through the first insulating layer, wherein the contact is laterally adjacent to the gate structure;
a metal layer disposed on the first insulating layer and in physical contact with the contact; and
a first dielectric layer covering a sidewall of the metal layer.

2. The semiconductor device of claim 1, further comprising a second insulating layer disposed on the first insulating layer.

3. The semiconductor device of claim 2, further comprising a second dielectric layer disposed on a sidewall of the first dielectric layer.

4. The semiconductor device of claim 3, wherein the second dielectric layer extends through the second insulating layer.

5. The semiconductor device of claim 4, wherein the second dielectric layer covers a top portion of the gate structure.

6. The semiconductor device of claim 3, further comprising a third insulating layer covering the metal layer.

7. The semiconductor device of claim 6, wherein the first dielectric layer and the second dielectric layer separate the sidewall of the metal layer from the third insulating layer.

8. The semiconductor device of claim 1, further comprising a well region disposed within the substrate, wherein the gate structure and the contact are in physical contact with the well region.

9. The semiconductor device of claim 8, further comprising an isolation structure disposed within the substrate, wherein the isolation structure laterally surrounds the well region.

10. The semiconductor device of claim 1, wherein the gate structure comprising:
a gate conductor disposed on the substrate;
an adhesion layer disposed on the gate conductor;
a conductive layer disposed on the adhesion layer; and
a hard mask disposed on the conductive layer.

11. The semiconductor device of claim 10, wherein the gate structure further comprising:
a spacer disposed on sidewalls of the gate conductor, the adhesion layer, the conductive layer, and the hard mask; and
a dielectric layer disposed on the surface of the spacer.

12. A method of forming a semiconductor device, comprising:
providing a substrate;
forming a gate structure on the substrate;
forming a first insulating layer covering the gate structure;
forming a second insulating layer on the first insulating layer;
forming a metal layer on the second insulating layer; and
forming a first dielectric layer covering a sidewall of the metal layer.

13. The method of claim 12, wherein forming the first dielectric layer comprises conformally depositing a first dielectric material layer, followed by etching back horizontal portions of the first dielectric material layer.

14. The method of claim 13, wherein the first dielectric material layer is deposited by atomic layer deposition.

15. The method of claim 13, wherein an opening is formed through the second insulating layer during the etching back of the first dielectric material layer.

16. The method of claim 15, wherein the opening exposes the gate structure.

17. The method of claim 16, further comprising conformally depositing a second dielectric material layer on the metal layer and the first dielectric layer, and in the opening.

18. The method of claim 17, wherein an anisotropic etching is performed on the second dielectric material layer to form a second dielectric layer.

19. The method of claim 18, wherein the second dielectric layer covers a sidewall of the first dielectric layer and an exposed portion of the gate structure.

20. The method of claim 12, further comprising forming a contact through the second insulating layer and the first insulating layer to electrically couple the metal layer and the substrate.
